(19) United States
(12) Patent Application Publication
(10) Pub. No.: US 2023/0178671 A1
(43) Pub. Date: Jun. 8, 2023

(54) PHOTOVOLTAIC MODULE

(71) Applicant: EURO COM PROJECT NOWINSKI, ZAMORCZYNSKA SP. J., Mogilno (PL)

(72) Inventors: Lukasz Nowinski, MOGILNO (PL); Dariusz Zamroczynski, Mogilno (PL)

(21) Appl. No.: 18/160,217

(22) Filed: Jan. 26, 2023

Related U.S. Application Data
(63) Continuation-in-part of application No. 16/003,410, filed on Jun. 8, 2018, now abandoned.

(30) Foreign Application Priority Data
Jun. 8, 2017 (PL) P.421831

(51) Int. Cl. H01L 31/05

(52) U.S. Cl. CPC H01L 31/0512; H01L 31/028

(57) ABSTRACT

A photovoltaic module is shown. The module is made up of a set of cells. Each cell comprises silicon while a graphene electrode is used for the connections. The electrode comprises a graphene grid or strips and is set in a polymer layer applied to the cells from both sides.

### PRIORITY CLAIM

The instant application is a continuation in part of U.S. Application Serial No. 16/003,410, filed on Jun. 8, 2018, presently pending, which in turn claimed priority to Polish Patent Application P.421831 filed on Jun. 8, 2017, presently pending, the contents of which is hereby incorporated by reference.

### FIELD OF THE INVENTION

The subject of the invention is a photovoltaic module, specifically its construction and way of connecting of the individual cells and elements that allow for maximal current efficiency, durability and resistance to the weather conditions.

### BACKGROUND OF THE INVENTION

Use of solar radiation in both, direct heating of rooms and buildings as well as electric energy generation by means of photovoltaic cells is more and more common.

Photovoltaic solar cells are basically known since the 80’s of the twentieth century. However, they are a more and more common source of electric energy thanks to more and more effective and cheaper methods of producing the solar panels and modules. A single cell is a semiconducting P-N or N-P plate wish an electrode made of metal, which is created on upper and lower surfaces of a plate. Electrodes of the upper (or frontal) side of the photovoltaic cells are usually formed as a group of endings connected by one or more rails. On the other hand, electrodes on the lower or back side of photovoltaic modules are formed as a continuous layers. Such a solutions are know from U.S. Pats. such as number 4434318 or number 4443652.

In principle, the biggest disadvantage of such a solution is the fact that it is strongly dependent on weather and time of the year when it comes to energy yield. Photovoltaic modules are coupled in a form of boards and together create PV modules, also called panels. The photovoltaic cells are joined serially and in parallel cater for adequate voltage and current supply.

A module’s efficiency in practice is not in 100% directly proportional to efficiency of each of individual modules coupled serially into the electrical matrix. When converting cells into panels the losses amount to up to 3-5% when using traditional “bus bar” technology. An example of such a solution is the panel description disclosed in European application EP3136448 A1.

### SUMMARY OF THE INVENTION

The aim of this invention is to eliminate the above flaws.

The essence of the solution is connecting individual cells with a graphene electrode in form of graphene network or graphene strips set in the polymer foil applied directly on both the cell on the exposed side as well as from the bottom.

### BRIEF DESCRIPTION OF DRAWINGS

The invention together with the above and other objects and advantages will be best understood from the following detailed description of the preferred embodiment of the invention shown in the accompanying drawings, wherein:

FIG. 1 depicts a schematic overview of a module;

FIG. 2 depicts an overview of joining of several layers of a module;

FIG. 3 depicts a schematic overview of a module;

FIGS. 4A - 4B depict a schematic of cells;

FIG. 5 depicts a schematic overview of a set of photovoltaic cells;

FIG. 6 depicts a schematic overview of graphene electrodes;

FIGS. 7A - 7C show embodiments of the system;

FIGS. 8A and 8B show additional cutaway views of the system; and

FIGS. 9A and 9B show connections used in an embodiment of the system.

### DETAILED DESCRIPTION OF THE INVENTION

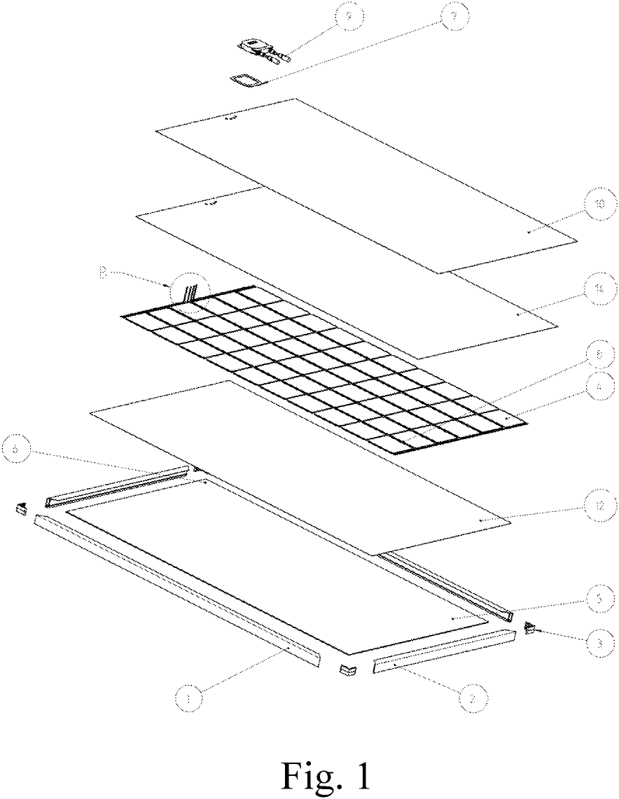

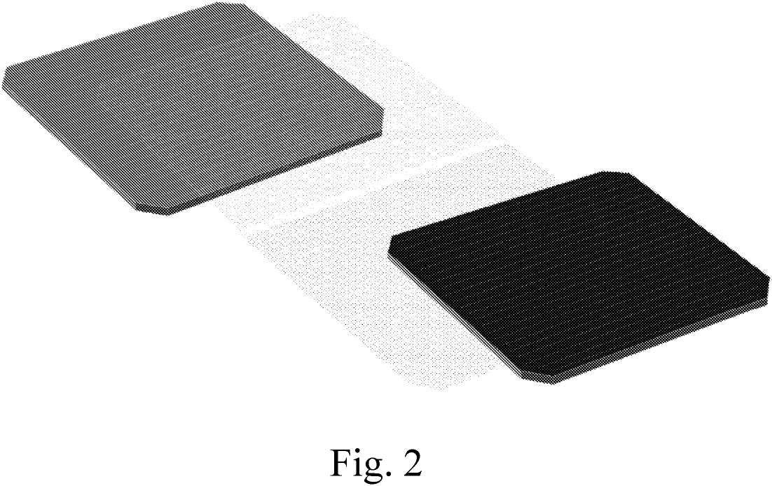

The invention is depicted in the example embodiment in the figures, but alternative embodiments are envisioned not restricted to the figures. FIG. 1 depicts a schematic of modules built by separating the elements, together with their layout after mounting, according to the invention. FIG. 2, on the other hand, shows schematics of joining graphene foil with photovoltaic cells.

The module consists of frames 1, 2 coupled with corners 3 holding the photovoltaic cells 4 covered with hardened glass sheet 5 with the anti-reflective layer 6. From the surface graphene electrodes 8 through the B connector the electric energy reaches the collector 9 joined through the seal 7. Photovoltaic cells modules are covered with EVA or TPO foil or film 12, 14 on both sides. From the bottom side, the panel is secured with a layer of silicone or PET film 10.

The created silico-graphene structure is far more resistant and durable due to the fact that silicone itself is twenty times more durable than steel. The PV modules created according to the invented technology have longer life expectancy and small vulnerability to micro fractures.

Moreover, the pane allows for gaining more than 50% more energy thanks to graphene matrix’s better reaction to the scattered light and in the situations when the matrix is in the shadow. Connection of single cells with a network of micro fibers lowers module’s sensitivity to the shading is minimal and the loss on electricity production is limited to a small area near the shaded place, not to the entire surface of the active module.

The photovoltaic module is characterized by the fact that connections of the individual silicon cells is done with use of graphene electrode in the form of full graphene grid or graphene strips set in polymer foil applied directly onto the cell from both sides, on the exposed side and on the underside.

### Additional Embodiments

As described above, the technology seeks to overcome the shortcomings and limitations of prior art “bus bar architecture. Instead, it uses a new generation of translucent graphene matrix of photovoltaic cells joined by a laminated layer. The cells are not soldered together. Other types of junctions eliminated form the embodiments of the invention include ribbons other thin conductors of an alloy of silver, copper, and aluminum, which are typically used in prior art devices. This decreases the costs of manufacturing and cuts down the amount of raw materials required to manufacture the photovoltaic module.

A goal of the embodiments is to increase the overall efficiency of the solar panels. In practice, module efficiency is not directly proportional to the efficiency of individual cells. There are conversion losses of cells when the cells are joined in a panel. In standard bus-bar technology, the grid density is low, with for example three paths transporting electrons in a cell.

As described herein, the construct does not suffer from efficiency losses and the overall system performance is directly proportional to the efficiency of individual cells due to the use of a new architecture of the photoelectric matrix. Other benefits of the matrix include resistance to microscopic damage, lower electrical resistance and higher light absorption by the matrix. As described below, the surface of the graphene foil, which is responsible for the transport of electrons in the cell, is several times higher in these embodiments. In some embodiments, the foil adheres to the entire cell and photoelectrons are transported for it’s entire surface.

In traditional bus-bar technologies, the useable life of a panel is limited by micro cracks in the structure of the silicon cells. Studies have shown that energy production suffers noticeable losses in traditional bus-bar architectures which develop micro-cracks in 1.67% (or one in sixty) of the cells, even in the remaining non-defective cells. Consequently, a module with defects negatively affects all other modules in the system connected in series, as happens in bus-bar architectures. Micro-cracks occur during exposure to temperature swings, but can also happen during manufacturing, when soldering of the cells requires temperatures in excess of 280° C.

The elimination of bus-bars reduces the creation of micro-cracks. The modules are exposed to temperatures which are half of the prior art approaches, or 140° C. Further, the use of the graphene electrode layer prevents the formation of micro-cracks. Even if the cells have defects, the malfunctioning cells do not have an impact on the remaining cells in the module due to the innovative architecture of the connection matrix and the graphene layer connecting it.

The embodiments described herein are able to obtain more than 50% more energy from each installed PV module, due to the better reaction of the graphene matrix to the scattered light and the low sensitivity of the innovative matrix to limited sunlight (such as when the sunlight is obscured by shadows).

The graphene layer, the photoelectric matrix technology are compatible with all types of standard crystalline cells, including hybrid cells. The technology has the potential to reduce costs by eliminating precious metals, such as silver, and rare elements such as indium. In some embodiments, the total thickness of the unit is reduced to 100 micrometers. Current panels are generally 200 micrometers in thickness and require indium during their manufacturing process.

The graphene-silicon module described herein has optimal abilities to dissipate heat. Initial measurements of thermal conductivity ranged from 4840±440 to 5300±480 W/mK, which is more than double that of diamond (whose thermal conductivity ranges from 900 to 2320 W/mK). Inability to dissipate heat in prior art modules is responsible for a significant reduction in the efficiency of electricity production, with some measurements suggesting that up to 71% of the loss of efficiency results when the modules exceed 25° C. or 77° F. The use of Graphene results in only a 0.5% loss of efficiency with each degree above 25° C.

This and other properties of the embodiments, such as not requiring high-temperature treatment, will significantly improve their useable life and sensitivity to micro-cracks. The use of graphene is also of benefit, as graphene itself is twenty times stronger than steel.

Overall system efficiency depends on manufacturing technology. Efficiency of most modules approaches 20%. Efficiency is also affected by the resistance of the DC conductors. Photovoltaic inverters have losses of 3-5%, which are compounded into the entire system. A very important feature of the embodiments of this system is the almost complete transparency. Non-cell components of the system absorb only 2.3% of the light. Gasses, even helium atoms, do not pass through the single layer. The speed of electrons moving through graphene is 1/300 of the speed of light, which facilitates the movement of photoelectrons in the PV module, resulting in efficiency exceeding 50% compared with the best produced PV modules.

The embodiment shown in FIG. 1 shows an example module with the front of the module shown on the bottom of the Figure. The module comprises a front glass 5, which serves a protection against damage to the PV module. The front glass 5 is toughened and its thickness varies between 2 mm and 4 mm. Most common PV modules use 3.2 mm glass, acting as a compromise between strength, weight, and cost. In most embodiments, the front glass 5 comprises solar glass with an anti-reflective coating (ARC glass).

The second layer is the EVA encapsulant, comprising a layer of TPO 12. A standard module design includes an EVA protective shell and a PET-based back shell. The disadvantage of this connection is degradation when the modules are exposed to moisture. A large power loss of the EVA modules has been observed in wet conditions. The layer of TPO 12 along with liquid silicone sealant has much better performance. Both materials provide protection against degradation.

Another layer of the module is the silicon cell 4. The module generates charges by optimal absorption of the light spectrum, but also ensures that surplus charges are efficiently collected with minimal conversion to the device electrode 8. The details of the electrode 8 are shown herein. The electrode 8 is the principal element facilitating collection of electric charge form the surface of cells.

While various coatings have been added to the emitter on the front or back (such as PERC - passive rear contact emitter), these are not used in every embodiment of the invention. Silicon dioxide SiO₂ is also a known alternative as a dielectric.

Behind the silicon cell 4 is another layer 14 of TPO. In some embodiments the layer 14 comprises EVA. The rear element is the backing 10. It is the coating that determines the useable lifespan of the module. The moduel is enclosed a by metallic frame elements 1, 2, 3, having a thickness of 30 mm to 50 mm. The frame comprises Aluminum, in one embodiment.

The module also includes a junction box 9 with a gasket 7.

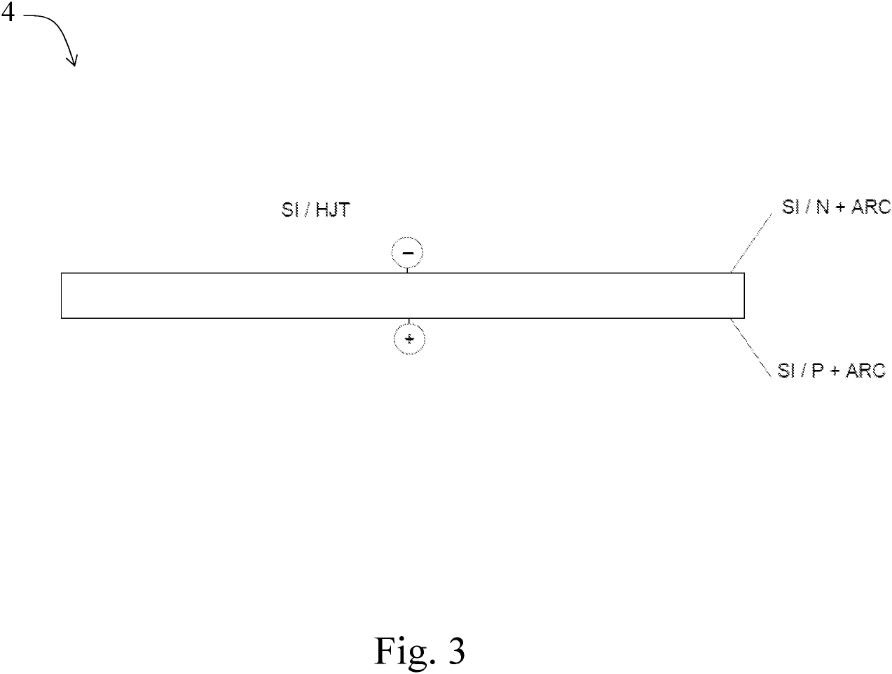

FIG. 3 depicts a schematic overview of the photovoltaic cell 4, as a component in the PV module. In some embodiments, the system can accommodate monocrystalline cells (ones made of monolithic crystal silicone), polycristaline cells made of crystallized silicon, amorphous cells of non-crystalized silicon, CdTe cells made with the semiconductor Telluride and Cadium, CIGS cells made of a mixture of semiconductors such as copper, indium, gallium, selenium. The system is also compatible with HJT and HIT cells built identically based on the PN junction, but not from crystalline silicon, but from amorphous silicon, CdTe, or a mixture of copper, indium, gallium, selenium (CIGS).

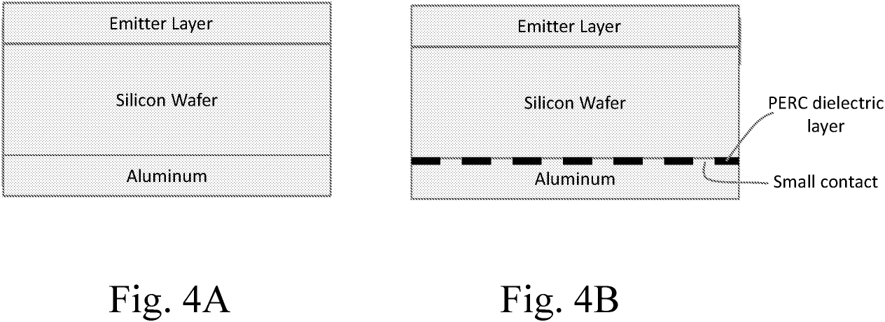

Schematic of cells are shown in FIGS. 4a and 4b. FIG. 4a depicts a schematic view of a conventional module, while FIG. 4b shows PERC technology. Both are compatible with embodiments of the system. PERC modules enable the cells to produce up to 12% more energy than a conventional solar panels. In some embodiments, both types of cells are combined in a deployed matrix of cells.

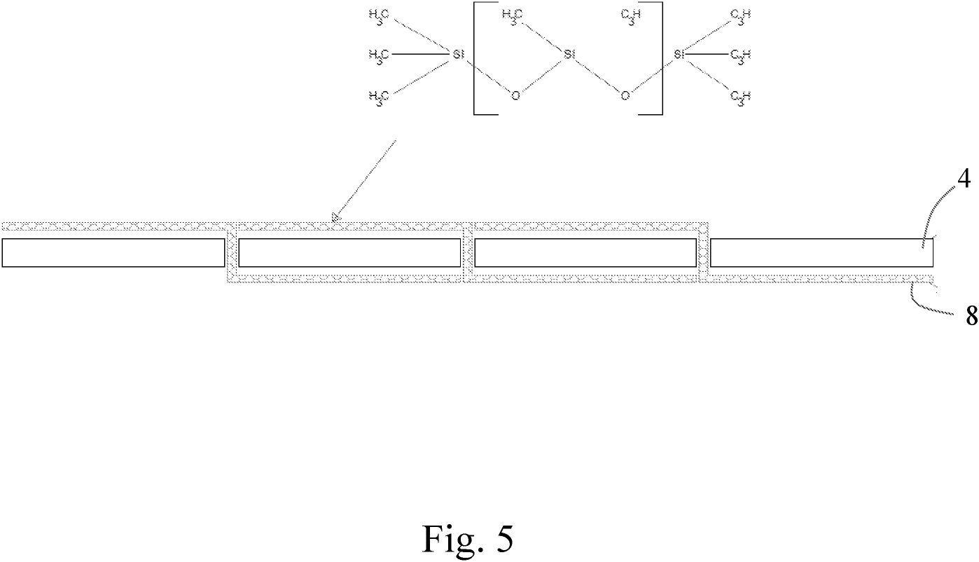

FIG. 5 shows a combination of PV cells 4, and the graphene electrode 8. The graphene used for this solution is produced using HSMG (high strength metallurgical graphene) method. Compared with other types of graphene, HSMG graphene has a higher strength and repeatability of physical and chemical properties in varying conditions including pressure and temperature.

The electrode is placed directly on the cells, in one embodiment, as shown in FIG. 2. In some embodiments, it is possible to transfer the electrode with the aim of transforming functional solar cells into more reliable modules while minimizing costs and losses. The technology changes the appearance of the front surface of the cells and offers additional benefits such as:

By connecting multiple wires, resistance losses protrusions in the surface of the cell can be reduced as the number of contact points can be tailored to the specific design of the cell.

Since the electrical conductor and a silver backing screen are not used in this process, the consumption of silver paste can be significantly reduced or even completely eliminated.

As a result of the transparent construction of the graphene electrode, the use of light in the module is extremely efficient.

The impact of cell breakage is decreased due to the high number of contact points within the cell.

The process steps are simplified because the lamination and soldering processes are combined into one step.

The technology reduces the impact on the cell because the temperature during the connection process is constant and kept below 160° C.

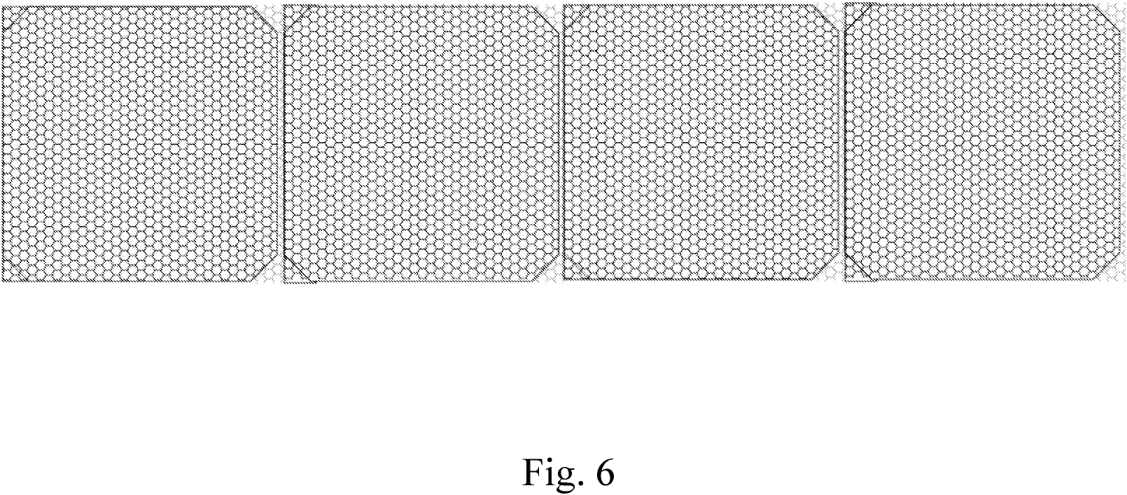

FIG. 6 shows how the cells are connected using the graphene electrode, which forms a mesh. The electrode comprises a honeycomb shape, in the depicted embodiment, but other shapes are appropriate depending on the shape of the cells. For example, the electrode can comprise a square, a hexagonal, or any other shape that is compatible with the cell geometry. The electrodes are shown in the figure, and the rest of each cell is not depicted. As described below, the electrode matrix can be used with a variety of cells.

While graphene is provided as a material for the electrode matrix, other materials can be used. For example, in other embodiments, the electrode matrix employs conductive metals, metal oxide, carbon or carbon nanotubes, etc. to create the desired electrode matrix.

The mesh elements (in some embodiments strips) are thin and flat reducing shadows cast and are made of strands of graphene. The strips are embedded in a polymer film that is applied directly to the metallized cell, and are all laminated together. The strips are connected to a conductor link and provide electrical conductivity for most materials used in cell construction. The number of graphene elements and their width can be adjusted to suit almost any cell design.

A benefit of the embodiment is that light-obscuring electrical conductors on the surface of the cell (front and back) are not needed, as occurs with traditional busbar technologies. This saves on material costs, such as the aforementioned use of silver-containing compounds. A benefit of the present system is that passive transfer at the cell can be achieved by using a full screen with a printed face. Additional components can be added to the construct to achieve passive energy generation effects (such as SiO, a-Si, AlOx etc) because the high temperature soldering steps are not necessary. Soldering of the contact wire and the metalized layers is reduced and high-temperature processing is altogether eliminated.

Another aspect of an embodiment of the invention using a graphene matrix is the durability of the matrix. A single layer of a matrix of thin conductors can elastically respond to changes in the environment. A conventional busbar will deform permanently when exposed to temperature extremes, for example. A conventional busbar also creates a single point of failure for all of the cells connected to that one busbar.

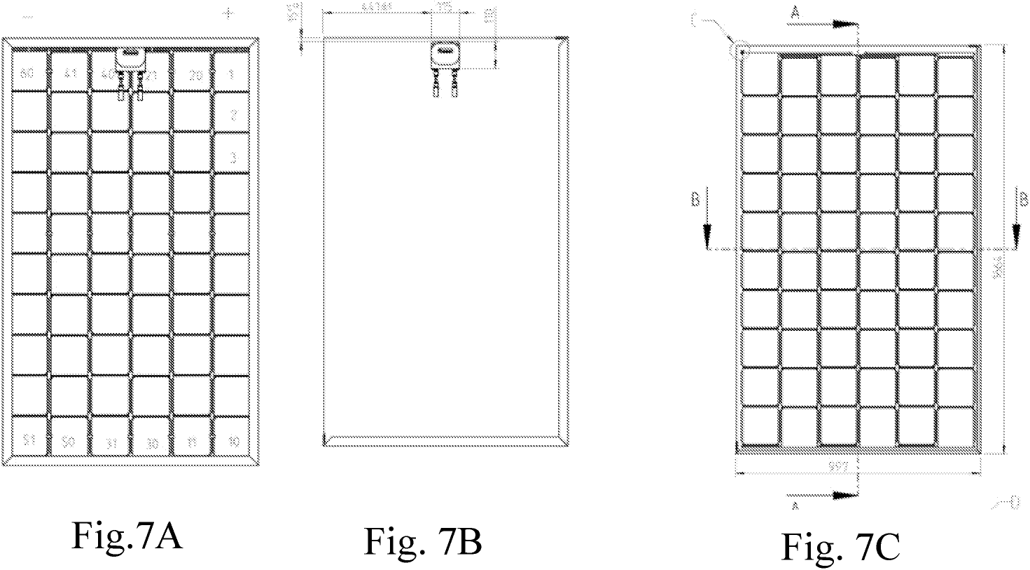

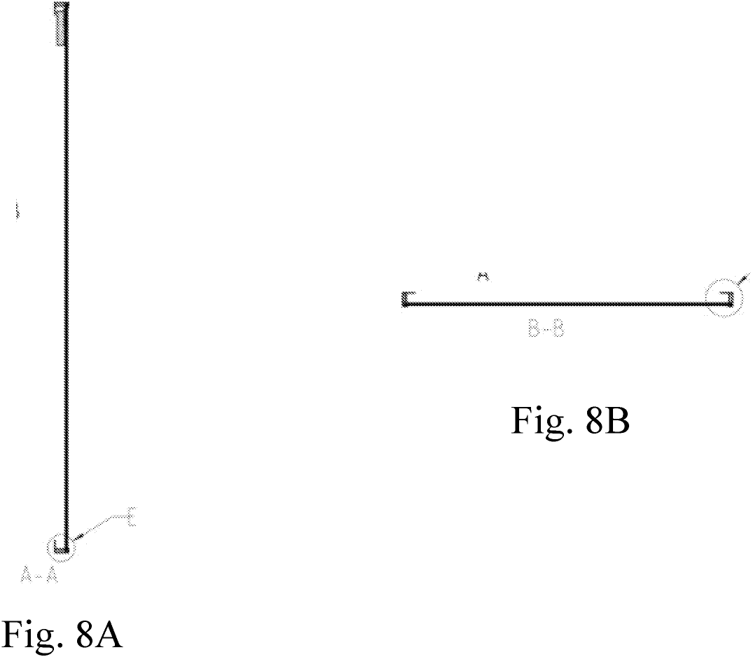

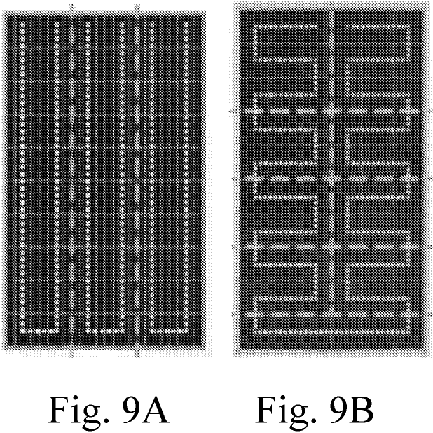

FIGS. 7A to 7C show embodiments of the system. FIG. 8A is a cut away view of FIG. 7C along the line A-A while FIG. 8B is a cut away view of FIG. 7C along line B-B. In one embodiment, the modules are built using 60 cells according to FIGS. 7A to 7C. However, construction of 72 and 96 cells is possible. Modules with 60 cells are 997 mm wide and 1664 mm long. In one embodiment, tach module will have 3 bypass diodes and therefore three sets of cells. Each set will contain 20 cells and the connections are shown in FIG. 9A. The graphene mesh solution allows building a 9-shunt PV module. Such a module contains 9 diodes and the cells are arranged as shown in FIG. 9B.

The graphene matrix can be used for modules that are bifacial. In addition to the higher amount of energy generated, bifacial modules offer advantages over standard single-sided modules.

Typically, double-sided modules are available as glass substrates or in some cases with transparent film substrates on the back screen. The foils on the back of the module usually have some water permeability allowing water to penetrate the back and enter the module and destroy it. On the other hand, the glass is completely impervious to water in the large rear screen area of the solar module, which as a result inhibits degradation effects such as oxidation and delamination. The only unprotected area in glass-glass modules are the edges, which are typically glued with double adhesive tape, silicone or a specially designed binder.

The solar cells themselves are protected by the distance between the edge of the module and the cell, water dissipates at the edge before any degradation takes place. The advantages of glass-glass modules are best used when using protective substances that do not contain or produce chemical components, but lead to the degradation of the cell’s metallization. Another advantage of glass-glass modules is greater flexibility, especially when using 2 mm thin glass, and their mechanical resistance resulting from the fact that the solar cell is located in a neutral position, which protects it from stretching and compression. Since mechanical stability is enhanced in glass-glass modules compared to glass-foil modules, frameless module designs are preferred. This is directly applicable in construction where integrated photovoltaics (BIPV) is used and reduces system costs. Frameless designs can minimize the risk of potential forced degradation (PID) in high-power systems because the driving force for PID is the potential between the grounded frame and the cell.

A key challenge for double-sided solar modules is the design and placement of the junction box. The size of the junction box should be minimized to minimize shading. Small junctions have to transmit more current, resulting in lower efficiency. The problems can be solved by cutting the cells in half and thus reducing the current in the cell. Alternatively, these cell-module losses can be reduced by an additional cell-level relay. In one embodiment, a combination of both solutions results in elimination of cell-module losses. As such, the graphene module is highly suitable as an internal connection for bifacial cells.

Mounting bifacial modules by cutting the cells in half can also optimize the power delivery through the rear side of the module, making it less sensitive to non-uniform irradiation of the rear surface in low elevation systems. In the case of double-sided solar cells, the back side consists of a similar network of graphene relays as the front side (unlike standard single-sided cells where the back side of the cell is fully conductive). This makes the cells transparent to IR radiation and leads to a lower operating temperature in the field.

Bilateral links have the potential to significantly reduce the complexity of the internal connection process. Some simplification can be achieved here by inverting the adjacent cell so that the graphene electrode does not have to intersect when running from the front side to the back side. This allows for an increase in productivity in the process of connecting cells, a reduction in the spaces between the cells and thus an increase in the reliability of the module in resisting thermomechanical pressures caused by temperature changes (typical testing from -40° C. to +85° C.).

Graphene interconnections requires cells with a high double-sidedness factor (>98%). Systems with z modules inclination are optimal, in the case of single-sided modules, they give the highest energy production and, accordingly, the lowest Levelized cost of electricity (LCOE). The LCOE will depend on the geographical location of the installation site and the base area.

In one embodiment, a TransWarp transfer foil used in the TPO 18 electrode is used, and for the EVA 12 electrode technology, graphene will be sprayed on the inside of the EVA-cell contact.

In other embodiments, a graphene on the back layer of the module and on the inside of the glass in order to improve the temperature coefficient of the module is used. Such embodiments have improved characteristics with Standard Test Conditions (STC) and especially for the Nominal Operating Cell Temperature (NOCT). In some embodiments, it is possible to completely eliminate the electrodes connecting the cells in series.

1. A photovoltaic module comprising:
at least one set of silicon photovoltaic cells;
a matrix conductor; and
at least one additional module layer;
wherein the at least one set of silicon photovoltaic cells are interconnected by the matrix conductor and covered by the at least one additional module layer.

2. The photovoltaic module of claim 1 wherein said matrix conductor comprises a matrix graphene electrode interconnecting individual photovoltaic cells comprising the at least one set of silicon photovoltaic cells.

3. The photovoltaic module of claim 1 further comprising connections between multiple sets of silicon photovoltaic cells.

4. The photovoltaic module of claim 3, wherein said connections between multiple sets of silicon photovoltaic cells comprise serial connections.

5. The photovoltaic module of claim 3, wherein said connections between multiple sets of silicon photovoltaic cells comprise parallel connections.

6. The photovoltaic module of claim 1, wherein said at least additional module layer comprises a polymer layer comprising EVA or TPO.

7. The photovoltaic module of claim 1, wherein said at least additional module layer comprises a protective film layer.

8. The photovoltaic module of claim 1, wherein said photovoltaic module excludes a busbar.

9. The photovoltaic module of claim 1, further comprising a collector wherein said collector provides an external electrical connection.

10. The photovoltaic module of claim 1, further comprising a frame.

11. The photovoltaic module of claim 1, wherein said frame comprises aluminum.

12. The photovoltaic module of claim 1, wherein silicon photovoltaic cells comprising at least one set of silicon photovoltaic cells comprise bifacial modules.

13. The photovoltaic module of claim 1, wherein silicon photovoltaic cells comprising at least one set of silicon photovoltaic cells at least sixty individual modules connected by the matrix conductor.

14. The photovoltaic module of claim 1, wherein said photovoltaic module excludes silver paste.

15. The photovoltaic module of claim 1, wherein said photovoltaic module excludes electrodes when the cells are connected in series.

16. The photovoltaic module of claim 1, wherein said module is expandable by addition of elements to the matrix conductor.

17. The photovoltaic module of claim 1, wherein said matrix conductor is placed on top of the at least one set of silicon photovoltaic cells.
